(19) United States
(12) Patent Application Publication
(10) Pub. No.: US 2011/0062390 A1
(43) Pub. Date: Mar. 17, 2011

(54) DERIVATIVES OF NANOMATERIALS AND RELATED DEVICES AND METHODS

(75) Inventors: Claudia Maria Cardona, Danville, VA (US); Martin Drees, Danville, VA (US); Brian Holloway, Danville, VA (US)

(73) Assignee: LUNA INNOVATIONS INCORPORATED, Roanoke, VA (US)

(21) Appl. No.: 12/743,121

(22) PCT Filed: Nov. 17, 2008
(86) PCT No.: PCT/US08/12844

§ 371 Date: Nov. 12, 2010

Related U.S. Application Data
(60) Provisional application No. 60/996,433, filed on Nov. 16, 2007.
(60) Provisional application No. 61/064,837, filed on Mar. 28, 2008.

(51) Int. Cl. H01B 1/12; C07F 3/00

(52) U.S. Cl. 252/519.2; 534/15; 534/16

(57) ABSTRACT

A functionalized trimetallic nitride endohedral fullerene based material can be represented according to the formula: A3-nXnN@Cm (R)o, wherein: where A and X are one or a combination of the following metal atoms: Sc, Y, La, Ce, Pr, Nd, Gd, Tb, Dy, Ho, Er, Tm, Lu; (n=0-3); N is nitrogen; Cm is a fullerene and m=about 60-about 200; and R is an organic, inorganic, or organometallic species. Related compositions, devices and methods are also described.

### FIELD

This disclosure relates to carbon-based nanomaterials and derivatives thereof, as well as related methods for their production, uses and devices or systems utilizing the same.

### BACKGROUND

In this specification where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

Throughout this disclosure, a number of patents, patent publications, and non-patent literature are referenced. Such references are to be construed as an incorporation by reference of the entire contents of each identified document herein.

Methods of making endohedral metallofullerenes have been previously described, for example, in U.S. Pat. No. 6,303,760. “Endohedral metallofullerenes” refers to the encapsulation of atoms inside a fullerene cage network. A family of trimetallic nitride endohedral fullerenes (TMS) can be represented generally as A₃₋ₙXₙN@Cₘ; where A and X are metal atoms, n=0-3, and m can take on even values between about 60 and about 200. All elements to the right of an @ symbol are part of the fullerene cage network, while all elements listed to the left are contained within the fullerene cage network. As an example, Sc₃N@C₈₀ indicates that a Sc₃N trimetallic nitride is situated within a C₈₀ fullerene cage. Trimetallic nitride endohedral fullerenes can have properties that find utility in conductors, semiconductor, superconductors, or materials with tunable electronic properties.

With increasing energy costs, the need for cheap renewable energy sources has become significantly more important. A promising cleantech approach to energy production is photovoltaics, which utilizes the direct conversion of sunlight into electric energy. Organic photovoltaic devices show particular promise because they have the potential for light-weight, flexible devices with potentially low material and production costs. Applications range from roof top photovoltaic systems to light weight, flexible solar cells integrated into tents, textiles and small electronic devices (i.e. cell phones, PDAs, etc.).

For example, published International Patent Application Publication WO 2005/098967 describes a photovoltaic device incorporating trimetallic nitride endohedral fullerenes.

### SUMMARY

Despite the foregoing, there is a need in the art for functionalized trimetallic nitride endohedral fullerene materials (“functionalized TMS”) having improved properties that make them useful, for example, as acceptor or donor materials in photovoltaic devices, as well as techniques for producing such materials. The invention described herein involves materials that are useful, for example, in forming the active layer of photovoltaic devices that will significantly improve the power conversion efficiency of organic solar cells thereby facilitating market acceptance of such devices. However, it should be understood that the materials of the present invention are not limited to this specific application, a number of beneficial uses of the materials of the present invention are envisioned.

According to one aspect, the present invention provides a composition comprising A₃₋ₙXₙN@Cₘ(R)ₒ, wherein:
A and X are metal atoms: Sc, Y, La, Ce, Pr, Nd, Gd, Tb, Dy, Ho, Er, Tm or Lu (n=0-3);
N is nitrogen;
Cₘ is a fullerene and m=about 60-about 200; and
R is an organic species. Also, R can be a mono-adduct (o=1) or a multi-adduct (1<o≦m).

The organic species comprising at least one of: PCBV, wherein PCB stands for phenyl (P), Cₘ₊₁ (C), butyric acid (B) or any other organic acid, and V is methyl (M), butyl (B), hexyl (H) or octyl (O); PCBW, wherein W is a modification to the side chains to induce more favorable interactions between the trimetallic nitride endohedral fullerene and the donor such as π-π or hydrogen bonding interactions. For example, W could be an ester and/or an amide which contains branching alkyl groups and/or aromatic moieties such as a phenyl, a thiophene, a pyrrole, or any structure that enhances interacting forces; ZCBW, wherein Z is a modification of the phenyl group which enhances the interactions mentioned above.

According to another aspect, the present invention provides a composition comprising A₃₋ₙXₙN@Cₘ (R)ₒ, wherein:
where A and X are metal atoms: Sc, Y, La, Ce, Pr, Nd, Gd, Tb, Dy, Ho, Er, Tm, Lu and n=0-3;
N is nitrogen;
Cₘ is a fullerene and m=about 60-about 200; and
R is an organic, inorganic, or organometallic species comprising specific characteristics that would enhance the efficiencies of donor/(A₃₋ₙXₙN@Cₘ) OPV devices. R can be linked to A₃₋ₙXₙN@Cₘ in any form such as, but not limited to, single bond to a carbon on the surface of the Cₘ cage; addends connected to two carbons on the surface of the carbon cage such as those that form a methano-bond as in the case of the methano-malonates and methano-malonamide or any other kind of 1,2-,1,3-, and/or 1,4-additions; any unsaturated bond; any dative or ionic bond; and/or any supra molecular interaction. Also, R can be a mono-adduct (o=1) or a multi-adduct (1<o≦m).

According to still another aspect, the present invention provides a method of forming a pyrrolidino-trimetallic nitride endohedral fullerene derivative, the method comprising: providing a trimetallic nitride endohedral fullerene material having a composition comprising A₃₋ₙXₙN@Cₘ(R)ₒ, wherein:

A and X are metal atoms: Sc, Y, La, Ce, Pr, Nd, Gd, Tb, Dy, Ho, Er, Tm or Lu; (n=0-3);

N is nitrogen;

Cₘ is a fullerene and m=about 60-about 200; and
R is a pyrrolidine addend (a five membered heteroatom ring) attached to the Cₘ carbon cage. Also, R can be a mono-adduct (o=1) or a multi-adduct (1<o≦m).

According to a further aspect, the present invention provides a method of forming a Diels-Alder fullerene derivative, the method comprising: providing a trimetallic nitride endohedral fullerene material having a composition comprising A₃₋ₙXₙN@Cₘ(R)ₒ, wherein:
A and X are metal atoms: Sc, Y, La, Ce, Pr, Nd, Gd, Tb, Dy, Ho, Er, Tm or Lu (n=0-3);
N is nitrogen;
Cₘ is a fullerene and m=about 60-about 200; and
R is a Diels-Alder (DA) adduct (a six member carbon or heteroatom ring) attached to the Cₘ carbon cage. Also, R can be a mono-adduct (o=1) or a multi-adduct (1<o≦m).

According to an additional aspect, the present invention provides a composition comprising AₙX_{q}YᵣN@Cₘ(R)ₒ where A, X, and Y are metal atoms: Sc, Y, La, Ce, Pr, Nd, Gd, Tb, Dy, Ho, Er, Tm or Lu; n=0-3, q=0-3, r=0-3, and n+q+r=3;

N is nitrogen;

Cₘ is a fullerene and m=about 60-about 200; and

(R)ₒ is a species formed according to any of the embodiments described herein.

According to a further aspect, the present invention provides a photovoltaic device having a donor or acceptor material comprising any of the foregoing compositions.

### BRIEF DESCRIPTION OF THE DRAWINGS

FIG. 1 is a schematic illustration of a photovoltaic device constructed according to one aspect of the present invention.

FIG. 2 is an energy level diagram for a polymer/fullerene system illustrative of certain principles of the present invention.

FIG. 3 is a schematic illustration of the chemical structures of exemplary functionalized TMS materials formed according to certain aspects of the present invention.

FIG. 4 is an illustration of two examples of methano derivatives according to the present invention.

FIG. 5 is an IV curve of an OPV device using a polymer/functionalized TMS material system.

FIGS. 6a-6b are schematic illustrations of the reactivity of TMS species in the formation of pyrrolidine derivatives, wherein Q is not equal to

H.

FIG. 7 is an illustration of the expected reactivity of TMS species in the formation of pyrrolidine derivatives, wherein Q is equal to H.

FIG. 8 is a schematic illustration of the synthesis of a C₆₀-PCBM derivative.

FIG. 9 is a schematic illustration of the synthesis of TMS/Diels-Alder monoadducts.

FIG. 10 illustrates the electronic differences of the Diels-Alder monoadducts as shown by their UV-visible spectra.

### DETAILED DESCRIPTION

The electronic structure of the trimetallic nitride endohedral fullerene distinguishes it from classic fullerenes and classic metallofullerenes due to the encapsulated metal-heteroatom/ion complex.

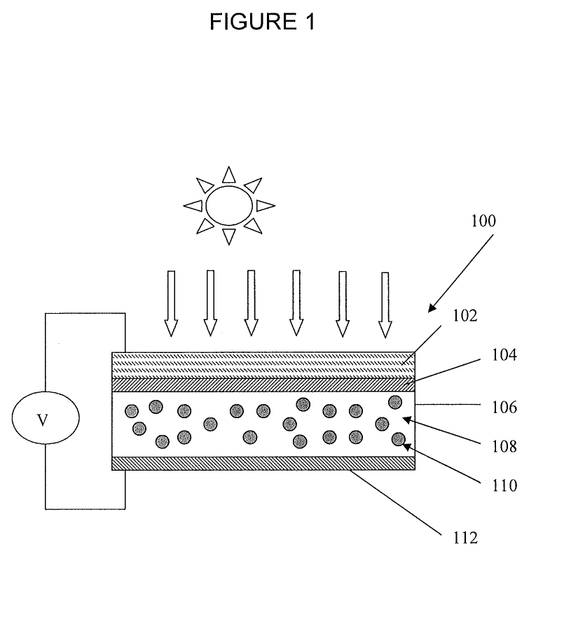

Trimetallic nitride endohedral fullerene materials can be used, for example, in photovoltaic devices. One of the most promising characteristics of fullerenes is their electron accepting ability which is critical in materials capable of absorbing energy with specific aims. An example of such a device is illustrated in FIG. 1. The device 100 illustrated in FIG. 1 is in the form of a bulk heterojunction photovoltaic cell. Typically, such cells include a transparent substrate 102 (e.g. glass, PET foil, etc.), a transparent electrode 104, and active layer 106, and a metal or conductive electrode 112. The active layer comprises a composite including a donor material 108 and an acceptor material 110.

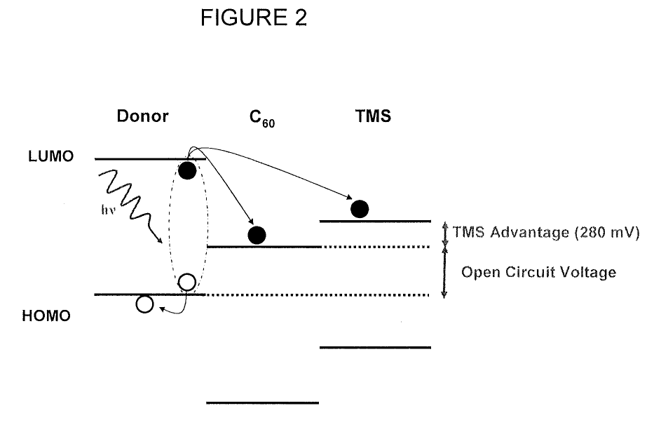

In bulk heterojunction photovoltaic cells, light absorption leads to excitons (electron/hole pairs) on the organic semiconductors that are separated at the donor/acceptor interface. Efficient charge separation at the donor/acceptor interface and transport through the separate phases of the interpenetrating networks to the respective electrodes is the basis for the photovoltaic effect in these devices. The interpenetrating molecular networks require nanoscale phase separation between the electron acceptor and electron donor species to achieve a distant charge-separated state, and allow enough time for the electrons and holes to flow in separate directions, and thus avoid recombination. Currently, most electron acceptors employed in Organic Photovoltaic Devices (OPVs) are derivatives of empty caged fullerenes. However, the molecular orbitals of fullerene acceptor materials, like C₆₀, C₇₀ and other empty cage fullerenes, have a large energy offset compared to the donor polymers. This leads to low voltages which affect the efficiency output of the devices. The working principle of an OPV device and the advantage of TMS materials are outlined in FIG. 2

Trimetallic nitride endohedral fullerene carbon nanomaterials are endohedral metallofullerenes consisting of a Cₘ cage enclosing a trimetal nitride cluster. Active layers including trimetallic nitride endohedral fullerene represent an improvement over existing acceptor materials for polymer/fullerene blend organic solar cells. For example, the molecular orbitals of TMS fullerenes can be tuned by the choice of enclosed metal and are better matched to the donor orbitals. Therefore, Trimetallic nitride endohedral fullerene carbon nanomaterials can significantly enhance the open circuit voltage of devices through better matching of the molecular orbitals of donor and acceptor material and have the potential to improve the quantum efficiency through reduced recombination versus empty cage fullerenes. Synthesis of TMS and functionalized TMS with different enclosed tri-metal nitrides allows tuning the energetics of the Lowest Unoccupied Molecular Orbital (LUMO) of the TMS material as well as the Highest Occupied Molecular orbital (HOMO). For example, producing a TMS material with LUMO levels that are positioned closer to the LUMO levels of commonly-used donor polymers should reduce the energy loss during electron transfer and should improve the open circuit voltage of the solar cell devices. Moreover, it has been shown that TMS materials may quench the photoluminescence of the polymer donor about as efficiently as conventional C₆₀ acceptor materials. This indicates that TMS materials dissociate the excitons on the polymer as efficiently as C₆₀ and therefore can be used as electron acceptor materials. In a similar manner, control can be exerted on the HOMO by substituting the nature of the metal in the trimetal nitride cluster inside the Cₘ cage. Sufficient offset of the HOMO levels of the donor and acceptor is required to prevent a competing energy transfer pathway that would interfere with the desired charge transfer pathway.

Thus, according to the present invention, a fullerene, endohedral metal fullerene, or trimetallic nitride endohedral fullerene, whether unfunctionalized or functionalized, is provided with the energetically highest observed LUMO with reduction potentials of <about −1.20 V to about −1.54 V vs. ferrocene/ferrocenium, relative to −1.20 V for C₆₀-PCBM, while displaying stability at ambient conditions. For example, Sc₃N@C₈₀-PCBM (1) displays a reduction at −1.368 V; Lu₃N@C₈₀-PCBH (9) undergoes a reduction at −1.50 V; the two monoadducts of 3-phenyl DA-Lu₃N@C₈₀ benzoate (15) have a reduction at −1.24 V and −1.28 V; and Y₃N@C₈₀-PCBH (18) undergoes a reduction at −1.46 V. The LUMO level is determined according to any suitable methodology such as Osteryoung Square Wave Voltammetry (SWV). These measurements were recorded on a CHI voltametric analyzer in o-dichlorobenzene (ODCB) using 0.05 M tetrabuyl-ammonium hexafluorophosphate (nBu₄NPF₆) as supporting electrolyte; a 1 mm glassy carbon as the working electrode; a platinum (Pt) wire as the counter electrode; and a silver (Ag) wire as the pseudo-reference electrode. The measurements were calibrated with the standard ferrocene/ferrocenium redox system.

Further, according to the present invention, a fullerene, endohedral metal fullerene, or trimetallic nitride endohedral fullerene, whether unfunctionalized or functionalized, is provided with the energetically lowest observed HOMO with reduction potentials of about +0.7 V to about 0.0 V vs. ferrocene/ferrocenium, relative to +1.1 V for C₆₀-PCBM, while displaying stability at ambient conditions. This characteristic makes them potential p-type, or donor, molecules. The HOMO level is determined according to any suitable methodology such as Osteryoung Square Wave Voltammetry (SWV). These measurements were recorded on a CHI voltametric analyzer in o-dichlorobenzene solvent (ODCB) using 0.05 M tetrabuyl-ammonium hexafluorophosphate (nBu₄NPF₆) as supporting electrolyte; a 1 mm glassy carbon as the working electrode; a platinum (Pt) wire as the counter electrode; and a silver (Ag) wire as the pseudo-reference electrode. The measurements were calibrated with the standard ferrocene/ferrocenium redox system.

However, low solubility of unfunctionalized or underivatized TMS molecules hampers their incorporation into devices. According to the present invention, the carbon cage of TMS donor or acceptor materials can be derivatized or functionalized with an organic group to improve the properties thereof, such as to improve their solubility in common conductive polymers used to form active layers in photovoltaic devices and/or to tune the LUMO level of the acceptor moiety to better match that of the donor depending of the site of addition, [5,6] vs. [6,6] on the carbon cage as in the case of A₃₋ₙXₙN@C₈₀. Thus, according to certain embodiments, the functionalized TMS materials of the present invention can be formulated according to the following formula:

A₃₋ₙXₙN@Cₘ(R)ₒ
wherein A and X are metal atoms: Sc, Y, La, Ce, Pr, Nd, Gd, Tb, Dy, Ho, Er, Tm or Lu; (n=0-3); Cₘ is a fullerene and m=about 60-about 200; and R=one or more organic groups. Examples of suitable organic groups include, but are not limited to, PCBV (B is any organic acid, such as butyric acid, and V=methyl, butyl, hexyl or octyl esters); PCBW (W=any modification to the side chains, including branched alkyl and/or aromatic esters, as well as branched alkyl groups and/or aromatic amides); ZCBW (Z is a modification of the phenyl group); Diels-Alder derivatives; and pyrrolidine derivatives. Also, R can be a mono-adduct (o=1) or a multi-adduct (1<o≦m).

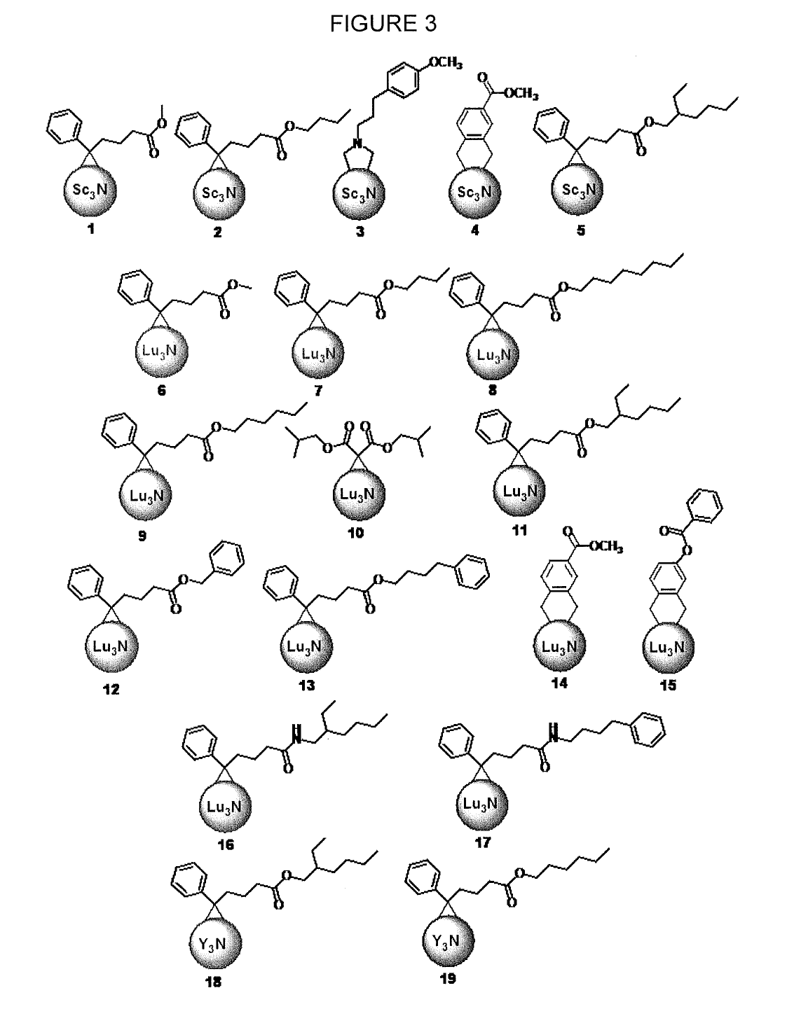

Specific non-limiting examples of functionalized TMS species of the present invention may include: Sc₃N@C₈₀-PCBM (1); Sc₃N@C₈₀-PCBB (2); N-(4-methoxyphenyl)ethyl Pyrrolido-Sc₃N@C₈₀ (3); methyl 3-benzoate DA-Sc₃N@C₈₀ (4); Sc₃N@C₈₀-PCBEH (5); Lu₃N@C₈₀-PCBM (6); Lu₃N@C₈₀-PCBB (7); Lu₃N@C₈₀-PCBO (8); Lu₃N@C₈₀-PCBH (9); Lu₃N@C₈₀-iPr-malonate (10); Lu₃N@C₈₀-PCBEH (11); Lu₃N@C₈₀-PCBMP (12); Lu₃N@C₈₀-PCBBP (13); methyl 3-benzoate DA-Lu₃N@C₈₀ (14); 3-phenyl DA-Lu₃N@C₈₀ benzoate (15); Lu₃N@C₈₀-PCB(EH)amide (16); Lu₃N@C₈₀-PCB(BP)amide (17); Y₃N@C₈₀-PCBH (18); and Y₃N@C₈₀-PCBEH (19). The chemical structures of these species are illustrated in FIG. 3.

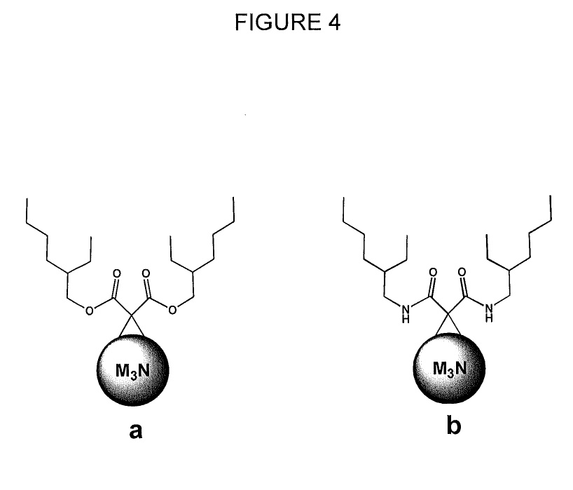

According to another embodiment, A and X are metal atoms: Sc, Y, La, Ce, Pr, Nd, Gd, Tb, Dy, Ho, Er, Tm, Lu; n=0-3; N is nitrogen; Cₘ is a fullerene cage; and R can be linked to A₃₋ₙXₙN@Cₘ in any form such as, but not limited to, single bond to a carbon on the surface of the Cₘ cage; addends connected to two carbons on the surface of the carbon cage such as those that form a methano-bond (see FIG. 4 for two examples) as in the case of the methano-malonates and methano-malonamide or any other kind of 1,2-,1,3-, and/or 1,4-additions; any unsaturated bond; any dative or ionic bond; and/or any supramolecular interaction.

R can be a mono-adduct (o=1) or a multi-adduct (1<o≦m). R is an organic, inorganic, or organometallic species comprising specific characteristics that would enhance the efficiencies of donor/(A₃₋ₙXₙN@Cₘ) OPV devices. The donor may be a conjugated polymer or small molecule. The efficiencies of such devices can be enhanced, according to the present invention, in one or more of the following ways:
a) R imparts A₃₋ₙXₙN@Cₘ with the ability to intimately interact with the donor polymer at the bulk heterojunction. This heterojunction is the surface where both the donor and acceptor components of an organic photovoltaic (OPV) device come in contact and the larger the volume of this surface, the more effective their interaction in a photovoltaic device. This interactive layer is crucial to the efficiency of the OPV device since the initial electron transfer occurs at this site. The inherent characteristics of R such as solubility, affinity, polarity, and/or size can be crucial to the formation of an effective bulk heterojunction since it would allow the A₃₋ₙXₙN@Cₘ closer access to the donor, and thus, a more effective electron transfer. In this case R can contain saturated alkyl (branched or un-branched) groups, un-saturated alkyl functionalities, aromatic moieties, polar entities and/or metals, and can also include any other fullerene or nanoparticle units.
b) R may also help increase the efficiency of the donor/(A₃₋ₙXₙN@Cₘ) OPV device by having the capability to absorb light in a wider range of the solar spectrum than the currently used donor molecules in OPV devices containing empty-cage fullerenes. In this case R comprises a chromophore such as a porphyrin, a phthalocyanine, or any inorganic/organic complex capable of absorbing light in any region of the solar spectrum, or an assemblage of such chromophores. Currently used materials have limited absorption ranges which leads to inefficient photon harvesting. Commonly used conducting polymers in photovoltaics, such as poly 3-hexyl thiophene (P3HT), have a moderate molar absorption coefficient in the visible region. An R group capable of absorbing solar light with higher quantum efficiencies and/or at wavelengths not utilized currently can lead to more effective harvesting of the solar spectrum which subsequently enhances the device efficiency. The charge or energy transfer from the R chromophore to the A₃₋ₙXₙN@Cₘ portion of the dyad can be controlled by the site of attachment of R to the Cₘ cage. For example, if the R is positioned at a double bond between a five-member and a six-member ring on the carbon cage, the charge transfer is expected to proceed in a more effective manner than in the case of R attached to an empty-cage fullerene. Such conclusion has been established from electrochemical experiments which have demonstrated that Sc₃N@C₈₀ substituted in this fashion has higher electron accepting capabilities than empty-cage-fullerenes. This is an example of an innate electronic property of A₃₋ₙXₙN@Cₘ which makes them so unique.
c) R enhances the formation of effective OPV films by facilitating interactions with the solvent system employed to prepare the OPV blend. This solvent system may be a single component or a mixture of components including additives, which interact to different extents with the polymer component and the A₃₋ₙXₙN@Cₘ (R)ₒ acceptor. This interaction can play a crucial role in the formation of a film structure which contains domains for the electron transfer to occur and an architecture that would allow for the holes and electrons to flow in opposite directions to the appropriate electrode which gives rise to an efficient photovoltaic effect. Thus, a range of materials can be incorporated into the blend solution to form the most effective films, including but not limited to solvent mixtures, organic or inorganic molecules, and/or nanomaterials. Examples of the additives range from small organic molecules to semiconductor particulate such as quantum dots to metal clusters or metal nanoparticles.
d) R is a species capable of, or modifier, that allows or encourages two-photon-absorption in the A₃₋ₙXₙN@Cₘ (R)₀ molecule. In two photon absorption, either R or the A₃₋ₙXₙN@Cₘ (R)₀ molecule absorbs two photons with energies below the band gaps of the donor and A₃₋ₙXₙN@Cₘ (R)ₒ that are converted to one photon that has the sum energy of the two absorbed photons. This way A₃₋ₙXₙN@Cₘ(R)ₒ can harvest low-energy photons that otherwise couldn't be harvested by the donor/(A₃₋ₙXₙN@Cₘ (R)ₒ) OPV device and thereby enhance the efficiency of the OPV device.
e) R is a species capable of, or modifier, altering the properties of the A₃₋ₙXₙN@Cₘ such that R or the molecule has an energy band system that has an intermediate band gap. In this case R or A₃₋ₙXₙN@Cₘ (R)ₒ can absorb photons with energy below the band gaps of the donor and A₃₋ₙXₙN@Cₘ that will lead to an excitation of the intermediate state and absorption of a second photon with energy below the band gaps of the donor and A₃₋ₙXₙN@Cₘ. This way the device can harvest low-energy photons that otherwise couldn't be harvested by the donor/(A₃₋ₙXₙN@Cₘ) OPV device and thereby enhance the efficiency of the OPV device.
f) R is a species capable of, or modifier, enabling the A₃₋ₙXₙN@Cₘ (R)₀ molecule to become capable of multiple exciton generation (6). In this process R or A₃₋ₙXₙN@Cₘ (R)ₒ absorbs photons with energy more than double the band gap of donor or A₃₋ₙXₙN@Cₘ and creates two excitons. These excitons will subsequently be separated into charges on the donor and A₃₋ₙXₙN@C₈₀. Thus the device will produce multiple charges out of one absorbed photon and thereby enhances the efficiency of the donor/(A₃₋ₙXₙN@Cₘ) OPV device.

There are specific findings relating to the materials and techniques of the present invention that are indicative of the advantageous characteristics thereof.

First, PCBM-Lu₃N@C₈₀ and PCBM-Sc₃N@C₈₀ may have an irreversible reductive behavior, unlike the reversible behavior of PCBM-C₆₀. The electrochemical reductive behavior is a “window” to the LUMO of the acceptor material, which is directly involved in the photovoltaic effect. Therefore, electrochemical characterization of fullerenes and their derivatives provides direct insight into their electronic structures and energy levels which can be used as an important tool in the alignment of molecular orbitals between donor and acceptor to optimize efficiencies. C₆₀ and its derivatives always demonstrate reversible behavior, including C₆₀-PCBM. Amazingly, the electrochemical reductive behavior of TMS analogue derivatives, such as TMS-PCBM, display kinetically irreversible reductive behavior. This enhanced resistance to part with the electron may prolong the lifetime of the charge separated state thus enhancing the photovoltaic effect in a bulk-heterojunction device. By contrast, such kinetic electrochemical irreversibility is not observed in fullerene species, such as C₆₀, C₇₀, or C₈₄, as well as their common derivatives. In addition, functionalized TMS materials can display reversible reductive behavior, depending on the site of addition of the functionalizing species (e.g., (R)); for example, some TMS materials such as Lu₃N@C₈₀, Sc₃N@C₈₀, Y₃N@C₈₀, etc., such as the Diels-Alder and pyrrolidino derivatives thereof, display a reversible behavior. This dichotomic electrochemical behavior is not observed in empty caged fullerenes.

In addition, even though the same side group functionalization was used for Lu— functionalized TMS and Sc— functionalized TMS (PCBM-Lu₃N@C₈₀ and PCBM-Sc₃N@C₈₀), the solubility behavior of the two is significantly different. The solubility of both of these is dramatically contrasting to C₆₀-PCBM which is extremely soluble in the solvents employed to fabricate photovoltaic devices. Lu₃N@C₈₀-PCBB is less soluble than Sc₃N@C₈₀-PCBB, leading to sediment in a P3HT:Lu₃N@C₈₀-PCBB blend solutions made at similar molecular ratios as Sc₃N@C₈₀-PCBM or C₆₀ PCBM. As a consequence, the fullerene content in the P3HT:Lu₃N@C₈₀-PCBB blends is rather low and at the moment undetermined. This issue was solved by modifications of the side group, the V in PCBV, to enhance the solubility. This modification entailed the elongation of the V carbon chain from B (butyl) to H (hexyl) and O (octyl).

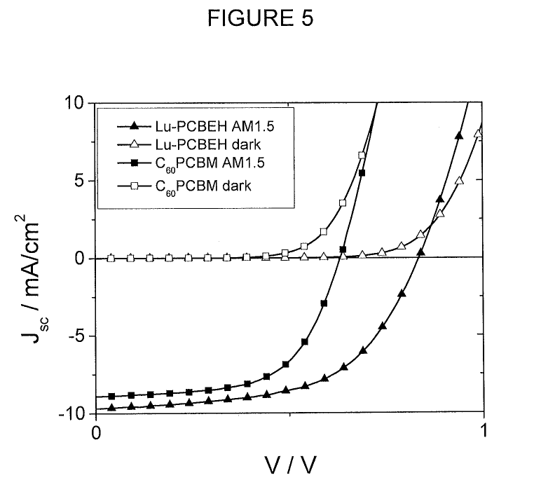

The device efficiency of Lu-TMS derivatives has already surpassed the efficiency of C₆₀-PCBM reference devices. Performance of a P3HT:Lu₃N@C₈₀-PCBEH device showing conversion efficiencies of 4.6% is illustrated in FIG. 5, which is an IV curve of a P3HT:Lu₃N@C₈₀-PCBEH device under simulated solar illumination at AM1.5 (100 mW/cm2). The fill factor of the P3HT:Lu₃N@C₈₀-PCBEH device matches that of the P3HT:C₆₀-PCBM device, the short circuit current is slightly higher in the P3HT:Lu₃N@C₈₀-PCBEH device while the open circuit voltage is 200 mV higher, demonstrating the advantage of the Lu-TMS derivative. The open circuit voltage in these devices has been observed in excess of 800 mV, and as high as 910 mV. That is the predicted limit for the Voc, as determined by electrochemical measurements.

According to further aspects of the present invention, specific techniques have been developed for producing functionalized TMS species of the type described herein. Specific illustrative, non-limiting techniques for functionalizing TMS materials are described below.

The reaction between paraformaldehyde (HCOH), a Q-N glycine (wherein N is the nitrogen of the glycine and Q stands for the substituent), and the trimetallic nitride endohedral fullerene gives rise to the thermodynamically most stable [5,6]-mono-adduct pyrrolidino derivative with the substituent on the nitrogen of the pyrrolidine ring.

The Q group can be an alkyl, an aryl or a combination of these wherein the alkyl is a carbon chain longer than 3 carbons. The most desirable derivatives introduce the Q group directly attached to the nitrogen of the amino acid since lesser isomeric form of the derivative are obtained due to the asymmetry of the surface of the carbon cage due to the lack of pyracyclene units found on C₆₀. Also, this Q group imparts stability on the pyrrolidine ring.

The synthetic procedure demanded a 1:10:50 ratio of the trimetallic nitride endohedral fullerene to the Q-N glycine (QNH—CH₂—COOH) to the paraformaldehyde and purification after the reaction had gone for only 10 minutes. In the case of C₆₀ and other empty cage fullerenes, the pyrrolidinofullerene mono-adduct was formed after 1 hour with the 1:2:5 ratio of C₆₀ to glycine to paraformaldehyde as described by Prato et al. (Journal of the American Chemical Society 1993, 115, 9798).

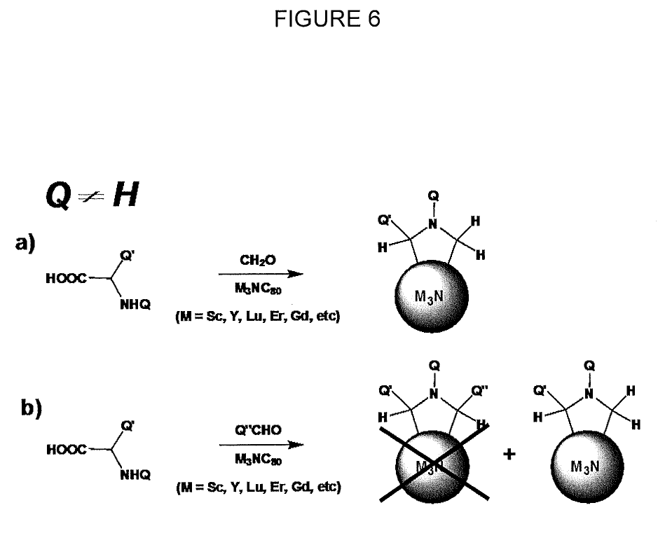

The pyrrolidine ring may require more substituents to enhance the solubility of the pyrrolidino-trimetallic nitride endohedral fullerene derivative to facilitate its incorporation in the photovoltaic devices. Thus, in the synthetic method used here, the substituents are introduced by the reaction between paraformaldehyde (HCOH), an Q-N Q′-glycine (wherein N is the nitrogen of the glycine and Q stands for the substituent on the nitrogen and Q′ is the substituent in the alpha carbon of the amino acid, QNH—(CHQ′)-COOH), and the trimetallic nitride endohedral fullerene (FIG. 6a). The Q and Q′ group can be an alkyl, an aryl or a combination of these wherein the alkyl is a carbon chain longer than 3 carbons.

The formation of pyrrolidinofullerenes with TMS follow unknown mechanistic pathways, unlike the reaction with empty cage fullerenes. For example, the recognized mechanistic pathway to form a pyrrolidinofullerene derivative involves a 1,3-dipolar cycloaddition reaction of an azomethine ylide with the empty fullerene cage at a [6,6]pyracyclene double bond. The azomethine is formed in situ by the reaction of the aldehyde (paraformaldehyde is often used) and the amino acid (glycine is often used). In order to introduce a substituent group or groups (Q, Q′, Q″) on the pyrrolidino moiety to make these types of derivatives more soluble, a Q″-aldehyde is often used with empty cage fullerenes. The Q″ group can be an alkyl, an aryl or a combination of these. However, this methodology does not work efficiently with trimetallic nitride endohedral fullerenes and little, if any, desired product is isolated as depicted by the “X” in FIG. 6b. In this case, the amino acid adds through an unknown mechanism to form the same expected product when the aldehyde is paraformaldehyde, but in much lesser quantities, as illustrated in FIG. 6a, and the incorporation of the Q″-aldehyde is not achieved.

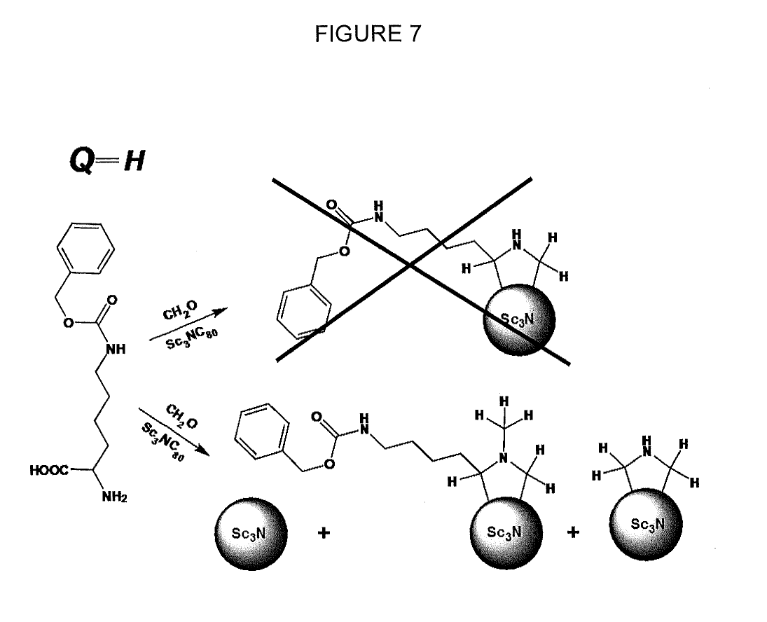

Therefore, the best strategy to introduce a group that increases the solubility of the pyrrolidino-trimetallic nitride endohedral fullerene derivative is to position the substituent(s) in the amino acid, and thus, both the expected 1,3-dipolar cycloaddition of the azomethine ylide, which is formed with paraformaldehyde, and the unexpected side reactions give rise to the desired product. This reactivity has been demonstrated with several TMS species as long as the amine of the amino acid employed is secondary in nature (Q≠H). If the amine of the amino acid used is primary in nature (Q=H), TMS fullerenes react in an unusual way and the little product recovered (indicated by the “X”) suggests other unknown reactions as depicted in the example given in FIG. 7. As shown therein, the expected pyrrolidine derivative was not formed, and instead two other pyrrolidine derivatives were formed in very low yields. The main material recovered was the unreacted trimetallic nitride endohedral fullerene employed, Sc₃N@C₈₀ in this case.

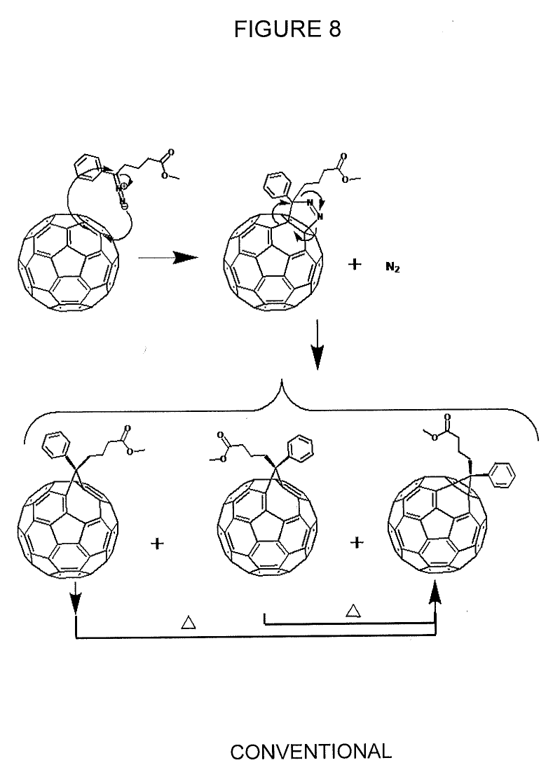

The addition of diazo groups to C₆₀ and other empty cage fullerenes is known. This methodology is employed to synthesize C₆₀-PCBM as depicted in FIG. 8. The addition of the hydrazone upon deprotonation followed by the elimination of nitrogen gives rise to three isomers. Upon heating, two of them isomerized into the third, a closed-[6,6]-monoadduct.

In the case of TMS, a single monoadduct is formed within 20 minutes of heating at 120° C. when a large excess of the hydrazone are used per equivalent of TMS under extreme anhydrous conditions in a pyridine-o-dichlorobenzene solution. The ratio employed is 1:10:10 of the trimetallic nitride endohedral fullerene to the hydrazone to the sodium methoxide. This reaction does not proceed with the nitride endohedral fullerene species following the conditions employed with C₆₀ as described by Hummelen (Journal of Organic Chemistry 1995, 60, 532-538) which only required a ratio of 1:2:2.08, respectively, stirring at 65-70° C. for 22 hours.

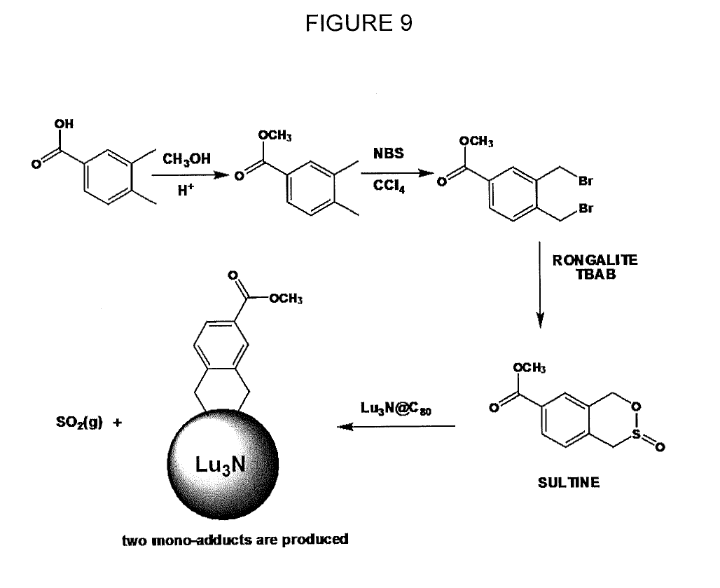

Diels-Alder cycloadditions have already proven successful on Sc₃N@C₈₀ (Dorn, et al. J. Am. Chem. Soc. 2002, 124, 524-525 and J. Am. Chem. Soc. 2002, 124, 3494-3495). However, herein we have synthesized TMS-Diels-Alder monoadducts under milder conditions, as illustrated in FIG. 9. The previous method required refluxing at very high temperatures to extract CO₂ from the 3-isochromanone to form the reactive o-quinodimethane in situ. To reach this high temperature a high-temperature refluxing solvent is required, such as 1,2,4-trichlorobenzene (b.p.=214° C.), which is difficult to remove after the reaction is completed. In our new scheme, the reactive o-quinodimethane is formed from a sultine (4,5-benzo-3,6-dihydro-1,2-oxathiin 2-oxide) which takes place by the extraction of SO₂ at lower temperatures (i.e. 120° C.) and the cycloaddition of the o-quinodimethane to the C₈₀ cage to form mainly two monoadducts (FIG. 9).

The ratio employed is 1:16 of the trimetallic nitride endohedral fullerene to the sultine in o-dichlorobenzene for 15 minutes. Diels-Alder monoadducts of C₆₀ have been prepared in a similar fashion, but once again, the product is only a monoadduct at the bond between two six-member rings (a pyracyclene) and the ratio used was 1:1 C₆₀ to sultine in toluene under refluxed for 6 to 24 hours.

A reactive o-quinodimethane is formed from a sultine (4,5-benzo-3,6-dihydro-1,2-oxathiin 2-oxide) which undergoes 4+2-cycloaddition (Diels-Alder mechanism) to a double bond on the C₈₀ cage.

As described above, the addend needs to carry substituents to enhance the solubility of the DA-trimetallic nitride endohedral fullerene derivative to facilitate its incorporation in the photovoltaic devices, thus we have selected a substituted o-xylene, for example 3,4-dimethyl benzoic acid, which facilitates the introduction of the substituent as an ester (e.g., FIG. 3, structures 4 and 14) or an amide at the carboxylic site. A 3,4-dimethylphenol (e.g., FIG. 3, structure 15), has also been used in the present invention.

The reactivity of the icoshedral (Iₕ) C₈₀ carbon cage differs tremendously from the Iₕ C₆₀ and other empty caged fullerenes that follow the isolated pentagon rule (IPR). One of the differences lies on the reactive sites for cycloaddition reactions.

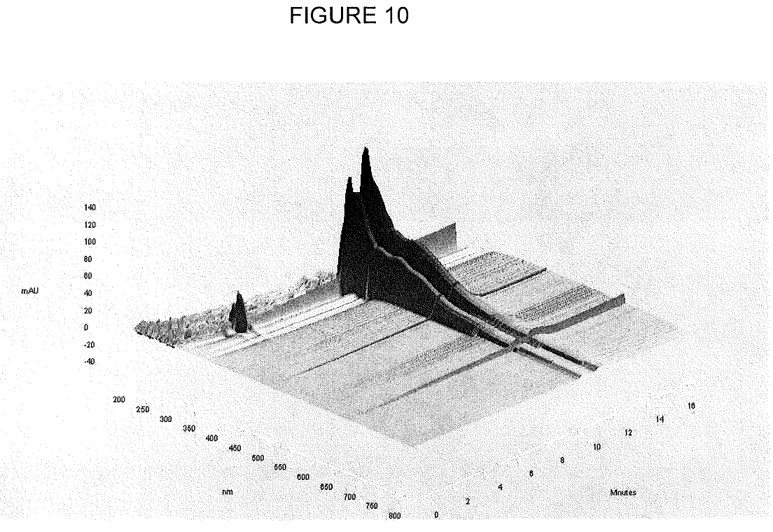

The C₆₀ cage is composed of reactive double bonds at junctures between two six-member rings abutted by two pentagons, pyracyclene units, or [6,6] sites. On its cage, there are no double bonds at [5,6] sites. The icoshedral C₈₀ cage, on the other hand, contains reactive double bonds at both [6,6]-ring junctions abutted by a pentagon and a hexagon (a pyrene-type site) and at [5,6]-ring junctions abutted by two hexagons (corannulene-type site). There are no pyracyclene units in the Iₕ, C₈₀ carbon cage. Thus, a Diels-Alder adduct on C₆₀ would be only positioned at a [6,6]-site while on C₈₀ we have isolated mainly two Diels-Alder monoadducts. Both isomers display different electronic properties (FIG. 10) as it was shown by Echegoyen et al. in the case of the pyrrolidino-[5,6] and [6,6] mono-adducts (Journal of the American Chemical Society 2006, 128, 6480). The advantage of the Diels-Alder mono-adducts is their stability which is lacking in the pyrrolidine examples, and thus, their incorporation in photovoltaic devices may enhance durability.

Malonate or malonamide derivatives are a type of methano derivatives. These also are positioned at pyracyclene units on the C₆₀ cage and other empty caged fullerenes, and the additional carbon forms a cyclopropane with the carbon cage. Thus, this reaction, a [2+1]cycloaddition of bromo- or iodo-diethylmalonateanion (the Bingel-Hirsch reaction) is often called cyclopropanation of fullerenes (C. Bingel, Chem. Ber., 1993, 126, 1957. A. Hirsch, I. Lamparth and H. R. Karfunkel, Angew. Chem., 1994, 106, 453; Angew. Chem., Int. Ed. Engl., 1994, 33, 437. A. Hirsch, I. Lamparth, T. Grösser and H. R. Karfunkel, J. Am. Chem. Soc., 1994, 116, 9385).

On the other hand, the reactivity of trimetallic nitride endohedral fullerenes has proven quite different towards this reaction. For example, the addition seems to occur generally at a pyrene-type site of the C₈₀ cage followed by a norcaradiene rearrangement which results in the opening of the cyclopropane ring. Consequently, the additional carbon becomes a bridge across a 10-carbon ring on the surface of the O₈₀ cage (Olena Lukoyanova, Claudia M. Cardona, José Rivera, Leyda Z. Lugo-Morales, Christopher J. Chancellor, Marilyn M. Olmstead, Antonio Rodríguez-Fortea, Josep M. Poblet, Alan L. Balch, and Luis Echegoyen, J. Am. Chem. Soc. 2007, 129, 10423).

The reaction conditions are also important. The usual reagents in the quantities employed in the Bingel-Hirsch reaction of C₆₀, for instance, do not work with the trimetallic nitride endohedral fullerenes. Very low yields on the methano adduct are obtained when Er₃N@C₈₀ or Y₃N@C₈₀ react with a malonate, carbon tetrabromide (CBr₄) and diazabicyclo[5.4.0]undec-7-ene (DBU). Unknown side reactions take place giving rise to un-identifiable products. Similar problems arise if iodine (I₂) is used instead of CBr₄. Nevertheless, conventional protocols for the cyclopropanation of C₆₀ require these reagents in the quantities specified at room temperature. The only experimental conditions that give rise to high yields of the methano derivative with the endohedral metallofullerenes calls for bromomalonate and DBU in amounts 10 times higher than those used for empty caged fullerenes or malonate with catalytic quantities of I₂ at 0-5° C. A short reaction time is also required to isolate the mono-adduct in high yields, otherwise the multi-adduct derivative becomes favored. Also, a single monoadduct is produced unlike the reactivity of other endohedral metallofullerenes such as La@C₈₂ which gives rise to four types of monoadducts (Lai Feng, Takatsugu Wakahara, Tsukasa Nakahodo, Takahiro Tsuchiya, Qiuyue Piao, Yutaka Maeda, Yongfu Lian, Takeshi Akasaka, Ernst Horn, Kenji Yoza, Tatsuhisa Kato, Naomi Mizorogi, and Shigeru Nagase, Chem. Eur. J. 2006, 12, 5578-5586).

Interestingly, the [2+1]cycloaddition of bromodiethylmalonate in the presence of DBU produced extremely stable derivatives with Y₃N@C₈₀, Er₃N@C₈₀ and Lu₃N@C₈₀ while Sc₃N@C₈₀ did not react under the same experimental conditions. Recently, diethyl malonate derivatives of Sc₃N@C₇₈ have been reported (Ting Cai, Liaosa Xu, Chunying Shu, Hunter A. Champion, Jonathan E. Reid, Clemens Anklin, Mark R. Anderson, Harry W. Gibson, and Harry C. Dorn, J. Am. Chem. Soc., 130 (7), 2136-2137, 2008) and only extreme radical conditions gave rise to a mixture of malonate isomers of Sc₃N@C₈₀ (Chunying Shu, Ting Cai, Liaosa Xu, Tianming Zuo, Jonathan Reid, Kim Harich, Harry C. Dorn, and Harry W. Gibson, J. AM. CHEM. SOC. 2007, 129, 15710-15717).

In addition, the malonate derivatives produced thus far with trimetallic nitride endohedral fullerene cannot be incorporated into current OPV processing techniques due to their low solubility. We have reached this conclusion based directly on our experimentation which revealed how important the R group is to the processing methodology and to the formation of an efficient heterojunction.

According to an additional embodiment, the present invention provides functionalized TMS materials formulated according to the following formula:

AₙX_{q}YᵣN@Cₘ(R)ₒ

where A, X, and Y are metal atoms: Sc, Y, La, Ce, Pr, Nd, Gd, Tb, Dy, Ho, Er, Tm or Lu; n=0-3, q=0-3, r=0-3, and n+q+r=3; N is nitrogen; Cₘ is a fullerene and m=about 60-about 200; and (R)ₒ is a species formed according to any of the embodiments previously described herein.

All numbers expressing quantities of ingredients, constituents, reaction conditions, and so forth used in the specification are to be understood as being modified in all instances by the term “about.” Notwithstanding that the numerical ranges and parameters set forth, the broad scope of the subject matter presented herein are approximations, the numerical values set forth are indicated as precisely as possible. For example, any numerical value may inherently contain certain errors resulting, for example, from their respective measurement techniques, as evidenced by standard deviations therefrom.

Although the present invention has been described in connection with preferred embodiments thereof, it will be appreciated by those skilled in the art that additions, deletions, modifications, and substitutions not specifically described may be made without departing from the spirit and scope of the invention.

1. A functionalized trimetallic nitride endohedral fullerene composition comprising:
A₃₋ₙXₙN@Cₘ(R)ₒ), wherein;
A and X are metal atoms: Sc, Y, La, Ce, Pr, Nd, Gd, Tb, Dy, Ho, Er, Tm or Lu;
n=0-3;
N is nitrogen;
Cₘ is a fullerene and m=about 60-about 200;
R is an organic species, an inorganic species or an organometallic species; and
1≦o≦m.

2. The composition of claim 1, wherein R possesses characteristics that enhance interactions between the trimetallic nitride endohedral fullerene and a donor material.

3. The composition of claim 1, wherein R is and organic species, the organic species comprising at least one of: PCBV, wherein PCB stands for phenyl (P), Cₘ₊₁ (C), butyric acid (B) or any other organic acid, and V is methyl (M), butyl (B), hexyl (H), or octyl (O); PCBW, wherein W is a modification to the side chains to induce more favorable interactions between the trimetallic nitride endohedral fullerene and a donor material; and ZCBW, wherein Z is a modification of the phenyl group which enhances the interactions between the trimetallic nitride endohedral fullerene and a donor material.

4. The composition of claim 3, wherein W comprises an amide which contains linear or branched alkyls groups and/or saturated or aromatic moieties.

5. The composition of claim 3, wherein W comprises an ester which contains linear or branched alkyl groups and or saturated or aromatic moieties.

6. The composition of claim 4, wherein the aromatic moieties comprise a phenyl, a thiophene, or a pyrrole, or a combination of aromatic groups.

7. The composition of claim 1, wherein R is linked to A₃₋ₙXₙN@Cₘ by one or more of: a single bond to a carbon on the surface of the Cₘ cage; addends connected to two-carbons on the surface of the carbon cage; a 1,2-,1,3-, and/or 1,4-addition; an unsaturated bond; an dative or ionic bond; or any supramolecular interaction.

8. The composition of claim 1, wherein R comprises a Diels-Alder (DA) adduct attached to the Cₘ carbon cage.

9. The composition of claim 1, wherein R possesses characteristics that improve the solubility of the composition in a polymer.

10. The composition of claim 1, wherein the composition comprises:
Sc₃N@C₈₀-PCBM; Sc₃N@C₈₀-PCBB; N-(4-methoxyphenyl)ethyl Pyrrolido-Sc₃N@C₈₀; methyl 3-benzoate DA-Sc₃N@C₈₀; Sc₃N@C₈₀-PCBEH; Lu₃N@C₈₀-PCBM; Lu₃N@C₈₀-PCBB; Lu₃N@C₈₀-PCBO; Lu₃N@C₈₀-PCBH; Lu₃N@C₈₀-iPr-malonate; Lu₃N@C₈₀-PCBEH; Lu₃N@C₈₀-PCBMP; Lu₃N@C₈₀-PCBBP; methyl 3-benzoate DA-Lu₃N@C₈₀; 3-phenyl DA-Lu₃N@C₈₀ benzoate; Lu₃N@C₈₀-PCB(EH)amide; Lu₃N@C₈₀-PCB(BP)amide; Y₃N@C₈₀-PCBH; or Y₃N@C₈₀-PCBEH.

11. The composition of claim 1, wherein R imparts A₃₋ₙXₙN@Cₘ with the ability to intimately interact with a donor polymer at a bulk heterojunction.

12. The composition of claim 11, wherein R comprises a saturated alkyl with branched or un-branched groups, un-saturated alkyl functionalities, aromatic moieties, polar entities, and/or metals.

13. The composition of claim 1, wherein R comprises at least one chromophore.

14. The composition of claim 13, wherein the chromophore possesses characteristics that improve the ability of the composition to harvest the solar spectrum.

15. The composition of claim 13, wherein the chromophore comprises porphyrin, a phthalocyanine, or an inorganic/organic complex capable of absorbing light in any region of the solar spectrum.

16. The composition of claim 1, wherein R possesses characteristics that facilitate interactions between a solvent system, a polymer, and the composition.

17. The composition of claim 1, wherein R possesses characteristics that facilitate two-photon absorption by the composition.

18. The composition of claim 1, wherein R possesses characteristics that enables the composition to become capable of multiple exciton generation.

19. The composition of claim 1, wherein the composition exhibits an irreversible reductive behavior.

20. The composition of claim 1, wherein the composition exhibits a reversible reductive behavior.

21. A functionalized trimetallic nitride endohedral fullerene composition comprising:
AₙX_{q}YᵣN@Cₘ(R)ₒ, wherein;
A, X and Y are metal atoms: Sc, Y, La, Ce, Pr, Nd, Gd, Tb, Dy, Ho, Er, Tm or Lu;
n=0-3;
q=0-3;
r=0-3;
n+q+r=3;
N is nitrogen;
Cₘ is a fullerene and m=about 60-about 200;
R is an organic species, an inorganic species or an organometallic species; and
1≦o≦m.

22. The composition of claim 21, wherein R possesses characteristics that enhance interactions between the trimetallic nitride endohedral fullerene and a donor material.

23. The composition of claim 21, wherein R possesses characteristics that improve the solubility of the composition in a polymer.

24. The composition of claim 21, wherein R imparts A₃₋ₙXₙN@Cₘ with the ability to intimately interact with a donor polymer at a bulk heterojunction.

25. The composition of claim 21, wherein R comprises at least one chromophore.

26. The composition of claim 25, wherein the chromophore possesses characteristics that improve the ability of the composition to harvest the solar spectrum.

27. The composition of claim 21, wherein R possesses characteristics that facilitate interactions between a solvent system, a polymer, and the composition.

28. The composition of claim 21, wherein R possesses characteristics that facilitate two photon absorption by the composition.

29. The composition of claim 21, wherein R possesses characteristics that enables the composition to become capable of multiple exciton generation.

30. The composition of claim 21, wherein the composition exhibits an irreversible reductive behavior.

31. The composition of claim 21, wherein the composition exhibits a reversible reductive behavior.

32. A material comprising the composition of claim 1.

33. The material of claim 32, wherein the material comprises a conductive polymer.

34. The material of claim 33, wherein the conductive polymer comprises poly 3-hexyl thiophene.

35. A photovoltaic device comprising the material of claim 32.

36. The device of claim 35, wherein the device comprises a bulk heterojunction type device.

37. A photovoltaic device, the device comprising an active layer, the active formed at least in part from the composition of claim 1.

38. The device of claim 37, wherein the active layer further comprises a conductive polymer.

39. A method of functionalizing a trimetallic nitride endohedral fullerene, the method comprising: reacting the trimetallic nitride endohedral fullerene with a paraformaldehyde (HCOH), and an amino acid such as Q-N Q′-glycine, wherein N is the nitrogen of the glycine, Q is a substituent on the nitrogen, and Q′ could be hydrogen or a second substituent on the alpha carbon of the amino acid.

40. The method of claim 39, wherein Q comprises one or more of: an alkyl and an aryl.

41. The method of claim 40, wherein the alkyl and aryl comprise a carbon chain longer than three carbons.

42. The method of claim 39, wherein the reaction is performed using a ratio of 1:10:50 of the trimetallic nitride endohedral fullerene to the Q-N glycine to the paraformaldehyde.

43. The method of claim 39, wherein the reaction occurs in 10 minutes or less.

44. A method of functionalizing a trimetallic nitride endohedral fullerene, the method comprising: reacting the trimetallic nitride endohedral fullerene with a hydrazone and sodium methoxide.

45. The method of claim 44, wherein the reaction is performed using a ratio of 1:10:10 of the trimetallic nitride endohedral fullerene to the hydrazone to the sodium methoxide.

46. The method of claim 45, wherein the reaction occurs at a temperature of at least about 120° C.

47. The method of claim 46, wherein the reaction occurs over period of time of 20 minutes or less.

48. A method of functionalizing a trimetallic nitride endohedral fullerene, the method comprising: reacting the trimetallic nitride endohedral fullerene with a sultine in a o-dichlorobenzene solvent.

49. The method of claim 48, wherein the reaction is performed using a ratio of 1:25:30 of the trimetallic nitride endohedral fullerene to sultine.

50. The method of claim 48, wherein the reaction is carried out for a period of time of 15 minutes or less.

51. The method of claim 48, wherein a substituted o-xylene is included in the reaction.

52. The method of claim 51, wherein the substituted o-xylene comprises 3,4-dimethyl benzoic acid.

53. A material comprising a fullerene, an endohedral metal fullerene, or a trimetallic nitride endohedral fullerene, the material comprising an energetically highest observed LUMO with reduction potentials of <about −1.20 V to about −1.54 V vs. ferrocene/ferrocenium.

54. The material of claim 53, wherein the material is functionalized.

55. A material comprising a fullerene, an endohedral metal fullerene, or a trimetallic nitride endohedral fullerene, the material comprising an energetically lowest observed HOMO with reduction potentials of about +0.07 V to about 0.0 V vs. ferrocene/ferrocenium.

56. The material of claim 55, wherein the material is functionalized.

57. A p-type or donor substance formed from the material of claim 55.
